(19) United States
(12) Patent Application Publication
(10) Pub. No.: US 2010/0017156 A1
(43) Pub. Date: Jan. 21, 2010

(54) REDUCTION OF NOISE IN ELECTRICAL FIELD MEASUREMENTS

(76) Inventors: Anton Ziolkowski, Edinburgh (GB); Richard Carson, Pebbles (GB)

Correspondence Address: E Eugene Thigpen;Petroleum Geo-Services Inc, P O Box 42805, Houston, TX, 77242-2805, US

(21) Appl. No.: 12/310,293

(22) PCT Filed: Aug. 23, 2007
(86) PCT No.: PCT/GB2007/003201

§ 371 Date: Aug. 28, 2009

(30) Foreign Application Priority Data
Aug. 24, 2006 (GB) 0616784.5

(51) Int. Cl. G01R 27/00; G01R 33/02

(52) U.S. Cl. 702/65; 324/244

(57) ABSTRACT

A method for removing cultural noise from a measurement of the field generated by an electromagnetic source, such as a current bi-pole or a magnetic loop source, the method comprising: simultaneously measuring the electromagnetic signal at a field measurement position and a calibration position close to the field measurement position, but in a null field of the source; using the field measurement and the calibration measurement to compute a filter that estimates the component of the field measurement that is correlated with cultural noise; convolving the computed filter with the calibration measurement to yield the estimated cultural noise component, and subtracting that component from the field measurement.

The present invention relates to a technique for reducing noise in electromagnetic field measurements. In particular, the present invention relates to a technique for reducing the impact of noise in multi-channel transient electromagnetic (MTEM) measurements.

### BACKGROUND OF THE INVENTION

Porous rocks are saturated with fluids. The fluids may be water, gas or oil or a mixture of all three. The flow of current in the earth is determined by the resistivities of such rocks, which are affected by the saturating fluids. For instance, brine-saturated porous rocks are much less resistive than the same rocks filled with hydrocarbons. By measuring the resistivity of geological formations, hydrocarbons can be detected. Hence, resistivity measurements can be made in an exploration phase to detect hydrocarbons prior to drilling.

Various techniques for measuring the resistivity of geological formations are known, for example time domain electromagnetic techniques, as described in WO 03/023452, the contents of which are incorporated herein by reference. Conventionally, time domain electromagnetic investigations use a transmitter and one or more receivers. The transmitter may be an electric source, that is, a grounded bipole, or a magnetic source, that is, a current in a wire loop or multi-loop. The receivers may be grounded bipoles for measuring potential differences, or wire loops or multi-loops or magnetometers for measuring magnetic fields and/or the time derivatives of magnetic fields. The transmitted signal is often formed by a step change in current in either an electric or magnetic source, but any transient signal may be used, including, for example, a pseudo-random binary sequence.

FIG. 1 shows a plan view of a typical setup for electromagnetic surveying with a current bi-pole source, for instance as described in U.S. Pat. No. 6,914,433. This has a current bi-pole source that has two electrodes A and B. In line with the source, is a line of receivers for measuring the potential between the pairs of receiver electrodes, for instance C and D. The source injects current into the ground and the response is measured between pairs of electrodes. Because of cultural electrical noise, especially where such measurements are made close to railways, overhead power lines and electrical machinery, the measured response is likely to be contaminated. Where very sensitive measurements are needed, this can be a significant problem.

### SUMMARY OF THE INVENTION

According to the present invention, there is provided a method for removing cultural noise from an electromagnetic measurement of the field generated by an electromagnetic source, such as a current bi-pole or a magnetic loop source, the method comprising simultaneously measuring the electromagnetic signal at a field measurement position and a calibration position close to the field measurement position, but in a null field of the source; using the field measurement and the calibration measurement to compute a function, preferably a filter, that estimates the component of the field measurement that is correlated with cultural noise; using the computed function, preferably filter, and the calibration measurement to yield the estimated cultural noise component, and subtracting that component from the field measurement to improve the signal-to-noise ratio.

The simultaneous measurement of the electromagnetic signal at the field measurement and calibration positions may be done when the source is off.

The electromagnetic field may be measured as current and/or voltage, preferably voltage.

The function may be a filter. The function may be convolved with the calibration measurement to yield the estimated cultural noise component.

This invention may be applied to any source that has a null field, for example, perpendicular to a particular axis. Examples include a current bi-pole source or a vertical loop magnetic source.

The receiver may comprise electrodes that are positioned substantially parallel to an axis of the source.

The calibration measurement may be done using calibration electrodes that are positioned perpendicular to and equidistant from an axis of the source, so that the measurement is made in the null electric field. If measuring the magnetic field, the calibration measurement may be made using a magnetometer positioned so that its axis extends along an axis of the source, so that the measurement is made in the null magnetic field.

The method may involve digitising the voltage measured at the receiver and the calibration electrodes.

The filter may be a causal filter, for example a Wiener filter.

According to another aspect of the present invention, there is provided a system for estimating noise in an electromagnetic measurement of the field generated by an electromagnetic source, such as a current bi-pole source or a magnetic loop, the system comprising: a receiver for measuring the electromagnetic field generated by the source at a measurement position and a calibration system for measuring the electromagnetic field at a position close to the receiver and in a null field of the source. The receiver and/or calibration system may be operable to measure current and/or voltage, preferably voltage.

The receiver may comprise electrodes that are positioned substantially parallel to an axis of the source. The calibration electrodes may be perpendicular to and equidistant from the axis of the source, so that the measurement is made in the null field.

The system may further include means for computing a filter from the calibration measurement and the electrical field measurement that estimates the component of the electromagnetic field measurement that is correlated with the noise measurement; convolving the computed filter with the calibration measurement to yield the estimated noise component, and subtracting that component from the electrical field measured at the receiver electrodes.

According to yet another aspect of the present invention, there is provided a computer program, preferably on a data carrier or a computer readable medium, having code or instructions for: using electric field measurements obtained simultaneously from a measurement position and a calibration position, the calibration measurement being substantially uncontaminated by noise from the source, to compute a filter that estimates the component of the electromagnetic field measurement that is correlated with the noise measurement; convolving the computed filter with the calibration measurement to yield the estimated noise component, and subtracting that component from the electrical field measured at the receiver electrodes.

### BRIEF DESCRIPTION OF THE DRAWINGS

Various aspects of the invention will now be described by way of example only and with reference to the accompanying drawings, of which:

FIG. 2 is a schematic view of a MTEM measurement system, and

FIG. 3 is a flow diagram of the method for estimating noise.

### SPECIFIC DESCRIPTION OF THE DRAWINGS

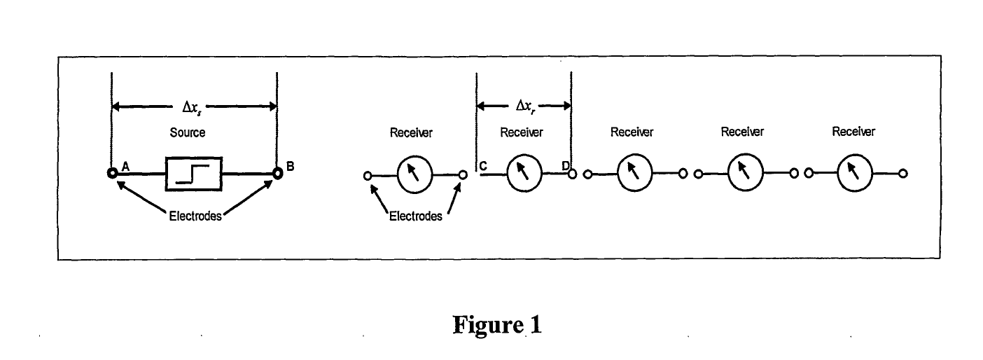

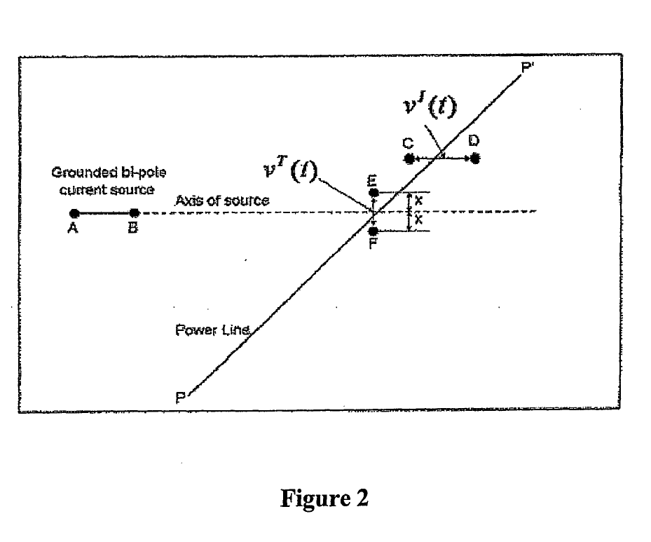

FIG. 2 shows a MTEM system that has a grounded bi-pole current source with electrodes A and B, a voltage receiver with grounded electrodes C and D and calibration electrodes E and F. Ideally, the current electrodes A and B and the receiver electrodes C and D are positioned along the same straight line, but in practice obstacles such as roads, buildings, etc. often force deviations. Hence, as shown in FIG. 2, the receiver electrodes C and D may be offset slightly from the axis of the source and cannot therefore measure the exact in-line voltage. In practice, the effect of the offset can be included in the processing of the data, but for the sake of clarity, in the following description, the measured voltage vs^{I}(t) is assumed to be in-line.

The in-line voltage signal vs^{I}(t), where I denotes in-line, measured at time t between the receiver electrodes C and D is contaminated by random noise na^{I}(t) and organised noise np^{I}(t). At higher frequencies the noise is often dominated by cultural noise, which can originate from, for example, railways, power lines (e.g. PP′ as shown in FIG. 2), electrical machinery, etc. At lower frequencies it is more likely to originate from the ionosphere and is known as magnetotelluric (MT) noise. The actual measured analogue voltage is the sum of the signal plus these two kinds of noise:

v^{I}(t)=vs^{I}(t)+na^{I}(t)+np^{I}(t). (1)

Cultural noise usually consists of a fundamental frequency and harmonics of that frequency. In Europe 50 Hz is the normal fundamental frequency, but near to electric railways there are other frequencies. MT noise is broad bandwidth and has increasing amplitude with decreasing frequency below about 1 Hz. There are situations where the organised noise is much bigger than the signal; that is, where

|np^{I}(t)|>>|vs^{I}(t)|. (2)

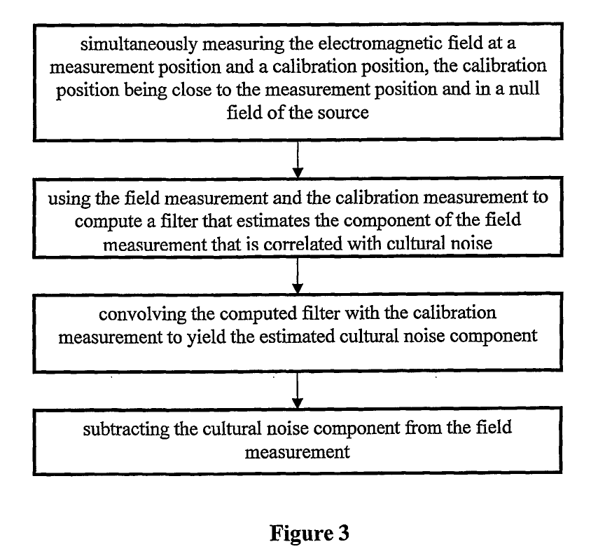

This can be a serious problem for the measurement of the signal vs^{I}(t). The present invention proposes a technique for reducing the impact of organised noise and so improving the signal-to-noise ratio. FIG. 3 shows the steps that have to be taken to do this.

Firstly, the voltage at the receiver electrodes C and D is measured simultaneously with the organised noise voltage between two calibration electrodes E and F, which are positioned near to the receiver CD, but uncontaminated by any signal. The field and calibration measurements are then used to compute a filter that estimates the component of the field measurement that is correlated with cultural noise. This filter is convolved with the calibration measurement to yield the estimated cultural noise component, which can then be subtracted from the field measurement to improve the signal-to-noise ratio. If the noise is stationary the filter does not change with time, so a filter determined at one time may be used at another time. In this case it would be preferable to compute the filter from data acquired at a time when the source is switched off.

To avoid signal contamination, the calibration electrodes E and F are perpendicular to the axis of the source and equidistantly spaced from that axis by an amount x, as shown in FIG. 2. Since the bi-pole source AB has no signal in the horizontal direction perpendicular to its axis—at least for a horizontally-layered earth—the calibration electrodes E and F lie in a null field of the source and so the voltage measurement made transverse to the source axis between the calibration electrodes E and F will be almost pure organised noise; that is,

v^{T}(t)≈np^{T}(t), (3)

in which the superscript T indicates the transverse direction. The measured transverse voltage will contain some random noise too, but for the purposes of this estimation, this is being neglected.

The relationship between np^{I}(t) and np^{T}(t) is assumed to be linear. That is, they are related by a linear filter f(t), such that

np^{I}(t)=np^{T}(t)*f(t)≈v^{T}(t)*f(t), (4)

in which the asterisk * denotes convolution. Using the voltage measured at the receiver electrodes C and D and the calibration electrodes E and E, the filter f(t) can be determined. The filter may be causal, or non-causal. If the filter is causal, it has no output before it has an input, so its response for negative times is zero; that is, f(t)=0 for negative times t. Once found, the filter can be convolved with the measurement v^{T}(t) to estimate np^{I}(t), which can be subtracted from the measurement v^{I}(t), as desired.

The problem of how to identify the filter can be formulated as a Wiener filter problem. In this case, the voltage measured at the calibration electrodes E and F, v^{T}(t), is used as an input signal and the voltage measured at the receiver electrodes C and D, v^{I}(t), as the desired output signal. A least squares filter is needed that will predict the component of v^{I}(t) that is related to v^{T}(t). The related component is of course the organised noise, since the signal is unrelated to the transverse voltage v^{T}(t). To do this, the analogue measurements v^{I}(t) and v^{T}(t) are first converted to discrete signals, vₖ^{I} and vₖ^{T}, respectively, using an analogue-to-digital converter, and sampled at a regular sample interval Δt that is small enough to preserve all the information. Analogue-to-digital conversion may be defined by the integral

$${x}_{k} = {\int }_{- ∞}^{∞} x ( t ) δ ( t - k Δ t ) d t , \qquad ( 5 )$$

in which δ(t) is the Dirac delta-function.

If the filter is causal it may be found according to Wiener's theory by solving the following equations

$${\sum }_{k = 0}^{n} {φ}_{TT} ( k - j ) {a}_{k} = {φ}_{IT} ( j ) , j = 0 , 1 , … , n \qquad ( 6 )$$

in which aₖ are the coefficients of the least-squares approximation to the digital filter fₖ, φ_{TT}(τ) is the auto correlation function of vₖ^{T},

$${φ}_{TT} ( τ ) = {\sum }_{k} {v}_{k}^{T} {v}_{k - τ}^{T} , \qquad ( 7 )$$

and φ_{IT}(τ) is the cross-correlation of vₖ^{I} with vₖ^{T},

$${φ}_{IT} ( τ ) = {\sum }_{k} {v}_{k}^{I} {v}_{k - τ}^{T} . \qquad ( 8 )$$

In summary, the causal Wiener filter may be found as follows: digitise the measurements v^{I}(t) and v^{T}(t) to yield vₖ^{I} and vₖ^{T}; compute the autocorrelation function φ_{TT}(τ) and the cross-correlation function φ_{IT}(τ), according to equations (7) and (8); and solve equations (6) to find aₖ. Fast algorithms for solving equation (6) are known.

Once aₖ is known, the digital noise signal npₖ^{I} is estimated by convolving the filter aₖ with the digital trasverse voltage vₖ^{T},

$${\overline{np}}_{k}^{I} = {\sum }_{j = 0}^{n} {a}_{j} {v}_{k - j}^{T} , \qquad ( 9 )$$

in which n̅p̅ₖ^{I} is the least-squares estimate of the noise npₖ^{I}. This may now be subtracted from vₖ^{I} to recover a better estimate of the signal:

v̅s̅ₖ=vₖ^{I}− n̅p̅ₖ^{I}, (10)

in which v̅s̅ₖ is the best estimate of the signal.

In the case that the filter is non-causal, it is necessary to put a known time delay of perhaps a few milliseconds into the measured signal v^{I}(t) and all the subsequent analysis is the same. For example, if the known time delay is τ, such that the time-delayed signal is

vd^{I}(t)=v^{I}(t−τ), (11)

then the signal vd^{I}(t) now replaces v^{I}(t) in the analysis and the resulting noise that is estimated is a delayed estimate of the real noise which may be subtracted from vd^{I}(t) to recover a delayed estimate of the signal. The delay is known throughout and may be removed at the end, if necessary.

In practice, it is not known whether the filter is causal or not, so it is necessary to introduce a long enough time delay τ that will make the filter causal. The value of τ can be found by trial and error. If τ is big enough, the first few coefficients of aₖ will be close to zero, demonstrating that the filter is now causal. If τ is not big enough, the first few coefficients of aₖ will be non-zero; in this case τ is varied until it is big enough. Another parameter that has to be chosen is n, where n+1 is the number of filter coefficients. This can also be found by trial and error. The filter must start at or close to zero, and must finish at or close to zero. So n must be big enough to achieve this.

The method of the present invention allows cultural noise and magnetotelluric noise to be estimated and subtracted from the measured electrical response of the earth. This can greatly improve the signal-to-noise ratio. For MTEM resistivity measurements in the field this is a significant advance.

Calculation of the noise may be done using any suitable software and/or hardware, for example a processor.

A skilled person will appreciate that variations of the disclosed arrangements are possible without departing from the invention. For example, the Wiener least-squares method proposed above to find an estimate of the filter f(t) is only one of several suitable methods. In addition, although FIG. 2 shows only one pair of receiver electrodes C and D and one pair of calibration electrodes E and F, since the organised noise can vary, the calibration measurement may be made for any receiver pair associated with the source. Hence, for every pair of receiver electrodes, there could be a corresponding pair of calibration electrodes. Also, although the simultaneous measurement of the electromagnetic signal at the field measurement and calibration positions may be done when the source is active, it could equally be done when the source is switched off. Accordingly the above description of the specific embodiment is made by way of example only and not for the purposes of limitation. It will be clear to the skilled person that minor modifications may be made without significant changes to the operation described.

1. A method for estimating noise in an electromagnetic measurement of the field generated by an electromagnetic source, such as a current bi-pole or a magnetic loop source, the method comprising:
simultaneously measuring the electromagnetic signal at a field measurement position and a calibration position close to the field measurement position, but in a null field of the source;
using the field measurement and the calibration measurement to determine a function that estimates the component of the field measurement that is correlated with noise; and
using the function and the calibration measurement to determine an estimate of the noise component.

2. A method as claimed in claim 1 wherein the electromagnetic field is measured as current and/or voltage.

3. A method as claimed in claim 1 comprising using a bipole electric source and measuring the calibration field using a magnetometer positioned so that its axis is substantially collinear with the axis of the bipole electric source.

4. A method as claimed in claim 1 comprising using a bipole electric source and measuring the calibration field using electrodes positioned perpendicular to and equidistant from an axis of the bipole source.

5. A method as claimed as claimed in claim 1 comprising using a magnetic loop source and measuring the calibration field using electrodes that are positioned on the axis of the magnetic loop source.

6. A method as claimed as claimed in claim 1 comprising using a magnetic loop source and measuring the calibration field using a magnetometer positioned so that its axis is substantially perpendicular to the axis of the magnetic loop source.

7. A method as claimed in any of claims 1 to 6 comprising digitising the voltage measured at the receiver and the calibration electrodes.

8. A method as claimed in any of claims 1 to 6 wherein the function is a filter.

9. A method as claimed in claim 8 wherein the filter is a causal filter.

10. A method as claimed in claim 8 wherein the filter is a Wiener filter.

11. A method as claimed in claim 1 wherein simultaneously measuring the electromagnetic signal at the field measurement and calibration positions is done when the source is off.

12. A method as claimed in claim 1 comprising subtracting the estimated noise component from the field measurement.

13. A system for estimating noise in an electromagnetic measurement of the field generated by an electromagnetic source, such as a current bi-pole source or a magnetic loop, the system comprising: a receiver for measuring the electromagnetic field generated by the source at a measurement position and a calibration system for measuring the electromagnetic field at a position close to the receiver and in a null field of the source.

14. A system as claimed in claim 13 wherein the receiver and/or calibration system are operable to measure current and/or voltage, preferably voltage.

15. A system as claimed in claim 13 wherein the calibration system includes a receiver that is positioned so that its axis is substantially parallel to the axis of the source.

16. A system as claimed in claim 13 wherein the calibration system includes a receiver positioned so that its axis is substantially perpendicular to the axis of the source.

17. A system as claimed in any of claims 13 to 16 comprising means for determining a function, preferably a filter, from the calibration measurement and the electrical field measurement that estimates the component of the electromagnetic field measurement that is correlated with the noise measurement; using the function, preferably filter, with the calibration measurement to yield the estimated noise component, and subtracting that component from the electrical field measured at the receiver.

18. A method for estimating noise in an electromagnetic measurement of the field generated by an electromagnetic source, such as a current bi-pole source or a magnetic loop, comprising:
determining a function that estimates the component of the electromagnetic field measurement that is correlated with noise using electric field measurements obtained simultaneously from a measurement position and a calibration position, the calibration measurement being substantially uncontaminated by the source, and
determining the estimated noise component using the function and the calibration measurement.

19. A method as claimed in claim 18 further comprising subtracting the estimated noise component from the electrical field measured at the measurement position.

20. A method as claimed in any of claims 1, 17 or 18 wherein the function is a time dependent function.

21. A method as claimed in any of claims 1, 17 or 18 wherein the function is a time independent function.
